(19) United States
(12) Patent Application Publication
(10) Pub. No.: US 2022/0175046 A1
(43) Pub. Date: Jun. 9, 2022

(54) REPLACEABLE DEVICE AND DETECTION METHOD THEREOF

(71) Applicant: Lanto Electronic Limited, Kunshan City (CN)

(72) Inventors: Lin WU, Kunshan City (CN); Yu MU, Kunshan City (CN); KaiHou WU, Kunshan City (CN); Hang YANG, Kunshan City (CN)

(73) Assignee: Lanto Electronic Limited, Kunshan City (CN)

(21) Appl. No.: 17/496,503

(22) Filed: Oct. 7, 2021

(30) Foreign Application Priority Data
Dec. 4, 2020 (CN) 202011399570.4

(51) Int. Cl. A24F 40/53; A24F 40/10; A24F 40/40

(52) U.S. Cl. CPC A24F 40/53; A24F 40/40; A24F 40/10

(57) ABSTRACT

The present disclosure provides a replaceable device and a detection method thereof. The replaceable device includes a main body and a replacement piece. The main body includes a detection circuit, and the detection circuit stores a usage count. The replacement piece is detachably connected to the main body, the replacement piece includes an identification circuit, and the identification circuit is electrically connected to the detection circuit. Wherein, when the detection circuit determines that the identification circuit is in a first state, the detection circuit resets the usage count and starts to count; when the detection circuit determines that the identification circuit is in a second state, the detection circuit continues the usage count and continues to count. Therefore, the present disclosure provides a replaceable device with high convenience, high safety, and high sanitary conditions.

### CROSS REFERENCE TO RELATED DISCLOSURE

This application claims the priority benefit of Chinese Patent Application Number CN202011399570.4, filed on Dec. 4, 2020, the full disclosure of which is incorporated herein by reference.

### BACKGROUND

### Technical Field

The application relates to the technical field of replaceable devices, particularly to a replaceable device and a detection method thereof.

### Related Art

As consumers have higher and higher requirements for products, the convenience, safety, and sanitary conditions of the products are gradually being valued. For consumers, replaceable devices have excellent convenience to be gradually accepted and used by consumers. For example, the replaceable device may be an electronic cigarette, a disposable needle tube, or other consumable products. After the contents (such as e-liquid or medicine) in the replacement piece are consumed by the user, the replaceable device may be reused quickly by replacing the replacement piece. In this way, fast and highly convenient effects may be achieved.

However, present replaceable devices do not have detection circuits. That is, when the contents in the replacement piece are consumed completely by a user, the replacement piece may be continued to use by privately adding the contents. The contents added privately may not have been tested. If the contents contain harmful substances or were contaminated in the adding process, such as adding too much e-liquid or other harmful ingredients to the cartridge of an electronic cigarette, which may cause safety and hygiene problems.

### SUMMARY

The embodiments of the present application disclose a replaceable device and a detection method thereof to solve the problem that is lacking the detection circuits in the present replaceable devices. The present replaceable devices are difficult to prevent users from adding content or modifying replacement pieces privately, resulting in poor safety and hygiene.

In order to solve the above technical problems, the present application is implemented as follows.

In the first aspect, the present application provides a replaceable device, comprising a main body and a replacement piece. The main body includes a detection circuit, and the detection circuit stores a usage count. The replacement piece is detachably connected to the main body, the replacement piece includes an identification circuit, and the identification circuit is electrically connected to the detection circuit. Wherein, when the detection circuit determines that the identification circuit is in a first state, the detection circuit resets the usage count and starts to count and accumulate the usage count; when the detection circuit determines that the identification circuit is in a second state, the detection circuit continues the usage count and continues to count and accumulate the usage count.

In the second aspect, the present application provides a detection method suitable for a replaceable device. Wherein the replaceable device includes a main body and a replacement piece. The replacement piece is detachably connected to the main body. The main body includes a detection circuit storing the usage count. The replacement piece includes an identification circuit electrically connected to the detection circuit. The detection method includes the steps of: detecting the identification circuit by the detection circuit in the replaceable device; determining whether the identification circuit is in a first state or a second state; when the identification circuit is in the first state, resetting the usage count and starting to count and accumulate the usage count; and when the identification circuit is in the second state, continuing the usage count and continuing to count and accumulate the usage count.

In the embodiment of the present application, the replaceable device of the present application detects the identification circuit disposed in the replacement piece through the detection circuit disposed in the main body. Therefore, the content of the replacement piece may be prevented from being replaced or re-added privately, result in ensuring the product's safety, and hygiene conditions.

### BRIEF DESCRIPTION OF THE DRAWINGS

The figures described herein are used to provide a further understanding of the present application and constitute a part of the present application. The exemplary embodiments and descriptions of the present application are used to illustrate the present application and do not limit the present application, in which:

FIG. 1 is a block diagram of the replaceable device according to an embodiment of the present application;

FIG. 2 is a block diagram of the replaceable device according to another embodiment of the present application;

FIG. 3 is a block diagram of the replaceable device according to a yet embodiment of the present application;

FIG. 4 is a schematic diagram of the replaceable device according to a yet embodiment of the present application; and

FIG. 5 is a flowchart of the detection method according to an embodiment of the present application.

### DETAILED DESCRIPTION OF THE EMBODIMENTS

In order to make the objectives, technical solutions, and advantages of the present application clearer, the technical solutions of the application will be described clearly and completely in conjunction with specific embodiments and the figures of the application. Obviously, the described embodiments are only a part of the embodiments of the application, rather than all the embodiments. Based on the embodiments in the application, all other embodiments obtained by a person of ordinary skill in the art without creative work fall within the protection scope of this disclosure.

The following description is of the best-contemplated mode of carrying out the invention. This description is made for the purpose of illustrating the general principles of the invention and should not be taken in a limiting sense. The scope of the invention is best determined by reference to the appended claims.

Moreover, the terms “include”, “contain”, and any variation thereof are intended to cover a non-exclusive inclusion. Therefore, a process, method, object, or device that comprises a series of elements not only includes these elements, but also comprises other elements not specified expressly, or may include inherent elements of the process, method, object, or device. If no more limitations are made, an element limited by “include a/an . . . ” does not exclude other same elements existing in the process, the method, the article, or the device which comprises the element.

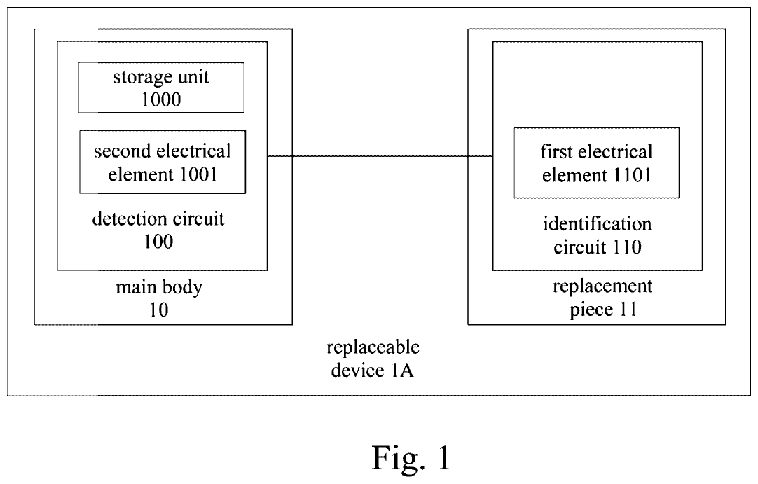

Refer to FIG. 1, which is a block diagram of the replaceable device according to an embodiment of the present application. As shown in the figure, the replaceable device 1A includes a main body 10 and a replacement piece 11. The main body 10 includes a detection circuit 100, and the detection circuit 100 stores a usage count. The replacement piece 11 is detachably connected to the main body 10. For example, the replacement piece 11 may be disposed on the main body 10 by snapping, screw locking, or magnetic adsorption. However, the present application is not limited thereto. Any connection manner recognized by a person of ordinary skill in the art may be applied to the present application. The replacement piece 11 includes an identification circuit 110, and the identification circuit 110 is electrically connected to the detection circuit 100. The identification circuit 110 may be in a first state or a second state, and the detection circuit 100 may detect and determine whether the identification circuit 110 is in the first state or the second state. When the detection circuit 100 determines that the identification circuit 110 is in the first state, the detection circuit resets the usage count and starts to count and accumulate the usage count; when the detection circuit determines that the identification circuit is in the second state, the detection circuit continues the usage count and continues to count and accumulate the usage count.

For example, when the replacement piece 11 disposed on the main body 10 is used, the detection circuit 100 in the main body 10 determines whether the identification circuit 110 in the replacement piece 11 is in the first state or the second state. When the replacement piece 11 disposed on the main body 10 is in the first state, the replacement piece 11 has not been used ever. That is, the replacement piece 11 will be used for the first time after being disposed on the main body 10. Then, the detection circuit 100 resets the stored usage count, that is, returns the stored usage count to zero, and the detection circuit 100 counts from zero. For example, the usage count is accumulated by 1 with each use of the replacement piece 11. Then, the detection circuit 100 stores the new usage count and records the new usage count in the detection circuit 100.

On the other hand, when the replacement piece 11 disposed on the main body 10 is in the second state, the replacement piece 11 has been used. Therefore, the detection circuit 100 continues to count the stored usage count and records the new usage count in the detection circuit 100. For example, the stored usage count is 10, and the new usage count accumulates to 11 after being used again and is recorded in the detection circuit 100.

In this way, the usage state and the usage count of the replacement piece 11 may be confirmed through the detection circuit 100 in the main body 10 and the identification circuit 110 in the replacement piece 11. Therefore, compared with a replaceable device without a detection circuit and an identification circuit, the replaceable device 1A of the present application has high convenience, high safety, and high sanitary conditions. Hereinafter, the details of each component or element will be explained in detail to make the technical features of the present application more obvious.

In some embodiments, the detection circuit 100 may include a storage unit 1000, and the storage unit 1000 stores a default parameter and the usage count. For example, the storage unit 1000 may be memory composed of semiconductor elements or memory composed of magnetic elements. More specifically, memory composed of semiconductor elements may be further classified into dynamic random access memory (DRAM), static random access memory (SRAM), and synchronous dynamic random access memory (SDRAM) according to the storage methods thereof. It should be noted that the memory types mentioned above are only examples, and the present application is not limited thereto. Any memory recognized by a person of ordinary skill in the art may be used in the present application.

In the case where the detection circuit 100 is disposed with the storage unit 1000, the identification circuit 110 may include the first electrical element 1101. Wherein, the detection circuit 100 is configured to detect the first electrical element 1101 to obtain a present parameter. Next, the detection circuit 100 compares the present parameter with the default parameter. When the present parameter matches the default parameter, the detection circuit 100 determines that the identification circuit 110 is in the first state. When the present parameter mismatches the default parameter, the detection circuit 100 determines that the identification circuit 110 is in the second state.

In some embodiments, the default parameter and the present parameter may include voltage values and/or current values. For example, the storage unit 1000 stores a default voltage value, and the detection circuit 100 determines the state of the identification circuit 110 by comparing the present voltage value of the first electrical element 1101 with the stored default voltage value. That is, when the present voltage value is equal to the default voltage value, the detection circuit 100 determines that the identification circuit 110 is in the first state. On the other hand, when the present voltage value is greater than or less than the default voltage value, the detection circuit 100 determines that the identification circuit 110 is in the second state. It should be noted that the default parameter and present parameter of this application are not limited to voltage value, current value, and combinations thereof. In other embodiments, the default parameter and the present parameter may also include other physical properties such as resistivity value, capacitance value, etc., based on the components that may be changed in physical properties included in the identification circuit.

In some embodiments, the detection circuit 100 may further include a second electrical element 1001. Wherein, when the detection circuit 100 determines that the identification circuit 110 is in the first state, the second electrical element 1001 changes the first electrical element 1101 to change the identification circuit 110 from the first state to the second state. For example, the replacement piece 11 with the identification circuit 110 in the first state is disposed on the main body 10. After the replacement piece 11 is used for the first time, the second electrical element 1001 changes the physical characteristics of the first electrical element 1101 to change identification circuit 110 to the second state. When the replacement piece 11 is used next time, regardless of whether the replacement piece 11 has ever been re-disposed in the main body 10, the identification circuit 110 of the replacement piece 11 is detected by the detection circuit 100 as the second state.

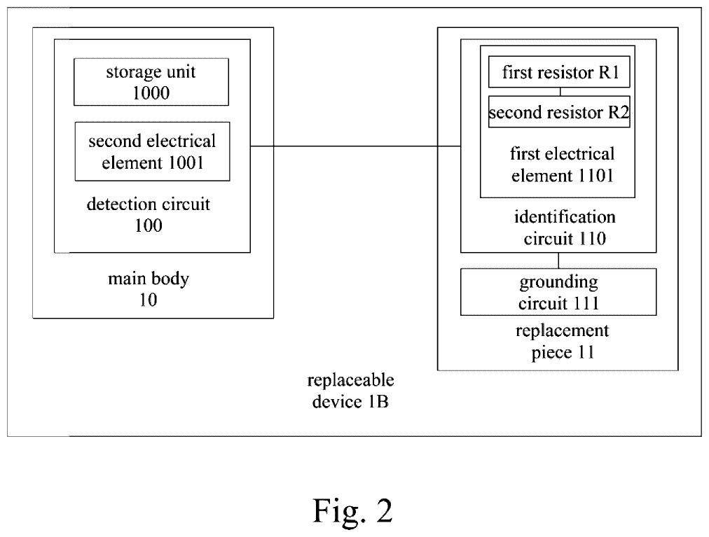

Refer to FIG. 2, which is a block diagram of the replaceable device according to another embodiment of the present application. In this embodiment, the same reference numerals indicate the same elements. Therefore, the detailed description of the same elements will be omitted. As shown in the figure, compared to the replaceable device 1A, the first electrical element 1101 in the replaceable device 1B may include a first resistor R1. The first resistor R1 may be a metal wire or a metal alloy wire (for example, a fuse). When the detection circuit 100 determines that the identification circuit 110 is in the first state, the second electrical element 1001 in the detection circuit 100 applies a specific voltage to the first resistor R1 to damage or fuse the first resistor R1. In this way, the physical characteristics (ie, present parameter) of the first electrical element 1101 is changed due to the damage or fusing of the first resistor R1. Further, the present parameter before the change may be equal to the default parameter, and the present parameter after the change may not be equal to the default parameter. In other words, the present parameter of the first electrical element 1101 is changed from the same as the default parameter to different from the default parameter, so that the identification circuit 110 is changed from the first state to the second state.

In addition, in some embodiments, the first electrical element 1101 may also include a second resistor R2. The second resistor R2 is connected in series with the first resistor R1. In this way, when the first resistor R1 is damaged or fuse, the detection circuit 100 may detect the present parameter through the voltage division.

In some embodiments, the replacement piece 11 may further include a grounding circuit 111, and the grounding circuit 111 is electrically connected to the identification circuit 110. Specifically, the grounding circuit 111 is used to provide a reference potential. Therefore, when the detection circuit 100 is electrically connected to the identification circuit 110, the present parameter based on the first electrical element 1101 in the identification circuit 110 may be determined more accurately.

In some embodiments, the detection circuit 100 may also store a preset usage count. When the usage count is equal to the preset usage count, the replacement piece 11 is not able to be used for the main body 10. Through the preset usage count, overusing of the contents of the replacement piece 11 is possible to be avoided. Overusing of the contents may cause damage to the device or release of toxic substances. For example, the replaceable device 1B may be an electronic cigarette component, that is, the content in the replacement piece 11 is e-liquid. When the content of the e-liquid is not enough, continuing to ignite the remaining e-liquid may cause the temperature of the replacement piece 11 to rise and release toxins, causing harm to the user. Therefore, by presetting the preset usage count to control the usage state of the replacement piece 11, the safety of the replaceable device 1B may be effectively improved.

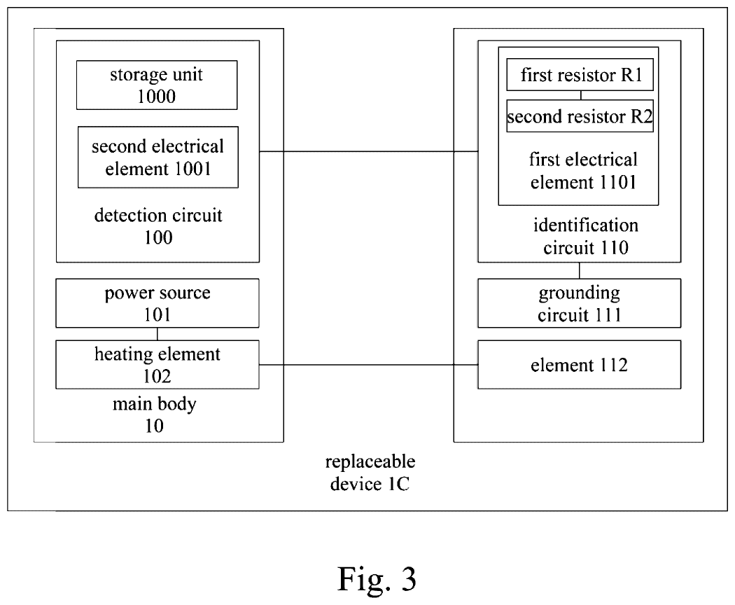

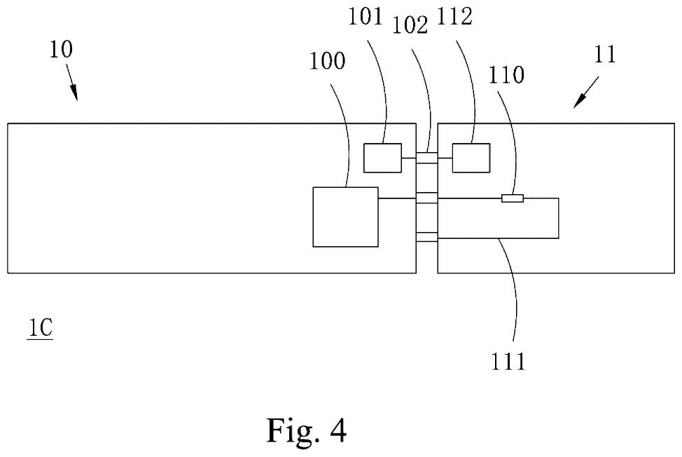

Refer to FIG. 3 and FIG. 4, which are respectively a block diagram and a schematic diagram of a replaceable device according to a yet embodiment of the present application. As shown in the figure, in actual applications, the replaceable device 1C may be applied to an electronic product that with the disposable replacement piece 11. For example, the replaceable device 1C may be an electronic cigarette component. Therefore, the main body 10 may be an electronic cigarette, and the replacement piece 11 may be a cigarette cartridge. In the present embodiment, the same reference numerals indicate the same elements. Therefore, the detailed description of the same elements will be omitted.

In this embodiment, the electronic cigarette as the main body 10 may further include a power source 101 and a heating element 102. For example, the power source 101 may be a lithium polymer battery. However, the present application is not limited thereto. The power source 101 may also be other types of batteries, such as lithium-ion batteries, nickel-cadmium batteries, nickel-hydrogen batteries, or any other batteries recognized by a person of ordinary skill in the art. The heating element 102 may be an atomizer. For example, the atomizer may be a rebuildable dripped atomizer (RDA), a rebuildable tank atomizer (RTA), or other types of atomizers.

On the other hand, the cartridge as the replacement piece 11 may also include an element 112 to be heated, and the heating element 102 is disposed corresponding to the element 112 to be heated. For example, the element 112 to be heated may be an oil tank that contains e-liquid. Therefore, the power source 101 supplies power to the heating element 102, so that the heating element 102 may heat the element 112 to be heated in the replacement piece 11. In this way, the contents such as e-liquid in the oil tank are heated by the atomizer into a gaseous state for the user to inhale. When the usage count is equal to the preset usage count, the replacement piece 11 is not able to be used for the main body 10. For example, the power source 101 stops supplying power to the heating element 102, so that the element 112 to be heated in the replacement piece 11 is not heated anymore.

In addition to being applied to electronic cigarettes, the replaceable device of the present application may also be applied to disposable medical equipment. For example, the replaceable device may be a medicament sprayer, the main body is a sprayer that may heat or atomize medicament, and the replacement piece may be filled with medicament. For example, the replaceable device may be a syringe assembly, the main body may be a syringe, and the replacement piece may be a disposable syringe. However, the syringes and disposable syringes mentioned above are only examples, and the present application is not limited thereto. For example, the replacement piece may also be a disposable catheter.

Hereinbefore, the various components and elements of the replaceable device of the present application have been explained in detail. Therefore, the detection method suitable for the replaceable device will be further described to make the technical features of the present application more obvious hereinafter.

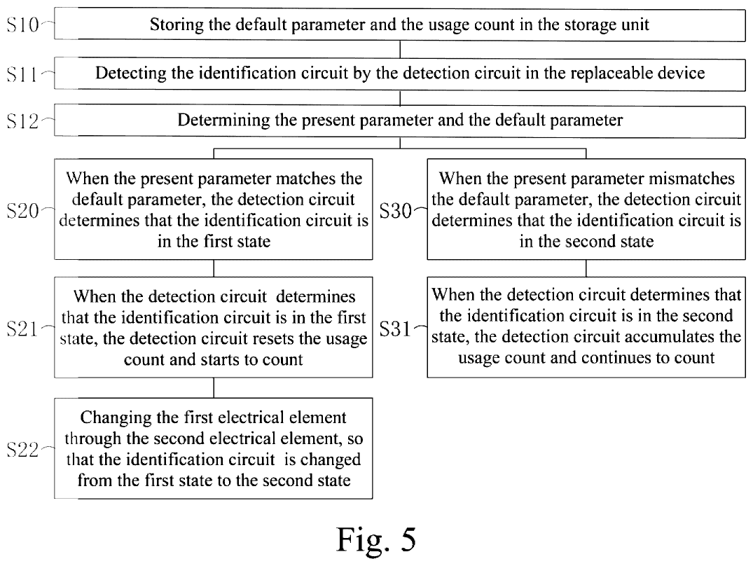

Refer to FIG. 5, which is a flowchart of the detection method according to an embodiment of the present application. The detection method of the present embodiment is applicable to any of the replaceable devices mentioned above. For example, the replaceable device may include a main body 10 and a replacement piece 11. The main body 10 includes a detection circuit 100 that stores a usage count and a default parameter, and the detection circuit 100 includes a storage unit 1000 and a second electrical element 1001. The replacement piece 11 is detachably connected to the main body 10, and the replacement piece 11 includes an identification circuit 110 electrically connected to the detection circuit 100. Wherein, the identification circuit 110 includes a first electrical element 1101, and the first electrical element 1101 includes a first resistor R1. As shown in the figure, the detection method includes:

Step S10: Storing the default parameter and the usage count in the storage unit 1000. In some embodiments, the default parameter may be a preset default voltage value, a default current value, and/or a default resistivity value.

Step S11: Detecting the identification circuit 110 by the detection circuit 100 in the replaceable device. In some embodiments, the detection circuit 100 measures the first resistor R1 in the first electrical element 1101 to obtain the present parameter of the first resistor R1 (for example, the present voltage value, the present current value, and/or the present resistivity value).

Then, the identification circuit is determined as the first state or the second state. When the identification circuit is in the first state, the detection circuit 100 resets the usage count and starts to count. When the identification circuit is in the second state, the detection circuit 100 continues the usage count and continues to count and accumulate the usage count. In some embodiments, the above method may be implemented in steps S12 to S31 in FIG. 5, as described below.

Step S12: Determining the present parameter and the default parameter. That is, whether the present voltage value, present current value, and/or present resistivity value of the first resistor R1 match with the default voltage value, default current value, and/or default resistivity value.

Wherein, when the present parameter matches the default parameter, the following steps are implemented:

Step S20: When the present parameter matches the default parameter, the detection circuit 100 determines that the identification circuit 110 is in the first state.

Step S21: When the detection circuit 100 determines that the identification circuit 110 is in the first state, the detection circuit 100 resets the usage count and starts to count.

Step S22: Changing the first electrical element 1101 through the second electrical element 1001, so that the identification circuit 110 is changed from the first state to the second state. For example, the first resistor R1 may be damaged or fused by being applied a specific voltage to the first resistor R1 from the second electrical element 1001, so that the first electrical element 1101 is changed.

On the other hand, when the present parameter mismatches the default parameter, the following steps are implemented:

Step S30: When the present parameter mismatches the default parameter, the detection circuit 100 determines that the identification circuit 110 is in the second state.

Step S31: When the detection circuit 100 determines that the identification circuit 110 is in the second state, the detection circuit 100 continues the usage count and continues to count and accumulate the usage count.

In summary, the replaceable device of the present application detects the identification circuit disposed in the replacement piece through the detection circuit disposed in the main body. Therefore, the content of the replacement piece may be prevented from being replaced or re-added privately, result in ensuring the product's reliability, safety, and hygiene conditions.

A person of ordinary skill in the art will understand current and future manufacturing processes, method and step from the content disclosed in some embodiments of the present disclosure, as long as the current or future manufacturing processes, method, and step performs substantially the same functions or obtain substantially the same results as the present disclosure. Therefore, the scope of the present disclosure includes the above-mentioned manufacturing process, method, and steps.

The above descriptions are only examples of this application and are not intended to limit this application. This disclosure may have various modifications and changes for a person of ordinary skill in the art. Any modification, equivalent replacement, improvement, etc. made within the spirit and principle of this application shall be included in the scope of the claims of this disclosure.

What is claimed is:

1. A replaceable device, comprising:
a main body comprising a detection circuit, wherein the detection circuit stores a usage count; and
a replacement piece detachably connected to the main body, wherein the replacement piece comprises an identification circuit, and the identification circuit is electrically connected to the detection circuit;
wherein when the detection circuit determines that the identification circuit is in a first state, the detection circuit resets the usage count and starts to count and accumulate the usage count; when the detection circuit determines that the identification circuit is in a second state, the detection circuit continues the usage count and continues to count and accumulate the usage count.

2. The replaceable device according to claim 1, wherein:
the detection circuit comprises a storage unit, and the storage unit stores a default parameter and the usage count,
wherein the identification circuit comprises a first electrical element, and the detection circuit is configured to detect the first electrical element to obtain a present parameter and compare the present parameter with the default parameter, and
wherein the detection circuit determines that the identification circuit is in the first state when the present parameter matches the default parameter; the detection circuit determines that the identification circuit is in the second state when the present parameter mismatches the default parameter.

3. The replaceable device according to claim 2, wherein:
the detection circuit further comprises a second electrical element, and
wherein when the detection circuit determines that the identification circuit is in the first state, the second electrical element changes the first electrical element to change the identification circuit from the first state to the second state.

4. The replaceable device according to claim 3, wherein the default parameter and the present parameter comprise a voltage value and/or a current value.

5. The replaceable device according to claim 3, wherein the first electrical element comprises a first resistor, and the second electrical element applies a specific voltage to the first resistor to damage or fuse the first resistor in order to change the first electrical element.

6. The replaceable device according to claim 1, wherein:
the detection circuit further stores a preset usage count, and
wherein the replacement piece is not able to be used for the main body when the usage count is equal to the preset usage count.

7. The replaceable device according to claim 1, wherein the replacement piece further comprises a grounding circuit, and the grounding circuit is electrically connected to the identification circuit.

8. The replaceable device according to claim 1, wherein:
the main body further comprises a power source and a heating element,
wherein the replacement piece further comprises an element to be heated, and the heating element is disposed correspondingly to the element to be heated, and
wherein the power source is configured to supply power to the heating element, and the heating element is used to heat the element to be heated in the replacement piece.

9. The replaceable device according to claim 1, wherein the main body is an electronic cigarette, and the replacement piece is a cartridge; or the main body is a syringe, and the replacement piece is a disposable needle tube.

10. A detection method suitable for a replaceable device,
wherein the replaceable device comprises a main body and a replacement piece, the replacement piece is detachably connected to the main body, the main body comprises a detection circuit storing a usage count, and the replacement piece comprises an identification circuit electrically connected to the detection circuit,
the detection method comprising:
detecting the identification circuit by the detection circuit in the replaceable device;
determining whether the identification circuit is in a first state or a second state;
when the identification circuit is in the first state, resetting the usage count and starting to count and accumulate the usage count; and
when the identification circuit is in the second state, continuing the usage count and continuing to count and accumulate the usage count.

11. The detection method according to claim 10, wherein the detection circuit comprises a storage unit, the identification circuit comprises a first electrical element, and the detection method further comprises:
storing a default parameter and the usage count in the storage unit;
detecting the first electrical element to obtain a present parameter;
determining the present parameter and the default parameter;
when the present parameter matches the default parameter, determining that the identification circuit is in the first state; and
when the present parameter mismatches the default parameter, determining that the identification circuit is in the second state.

12. The detection method according to claim 11, wherein the detection circuit further comprises a second electrical element, and when the identification circuit is in the first state, the detection method further comprises:
changing the first electrical element by the second electrical element to change the identification circuit from the first state to the second state.

13. The detection method according to claim 12, wherein the first electrical element comprises a first resistor, and the detection method further comprises:
applying a specific voltage to the first resistor by the second electrical element to damage or fuse the first resistor in order to change the first electrical element.

14. The detection method according to claim 13, wherein the default parameter and the present parameter comprise a voltage value and/or a current value.

15. The detection method according to claim 10, wherein the detection circuit further stores a preset usage count, and
wherein the detection method further comprises:
when the usage count is equal to the preset usage count, having the replacement piece unable to be used for the main body.

16. The detection method according to claim 10, wherein the replacement piece further comprises a grounding circuit, and the grounding circuit is electrically connected to the identification circuit.

17. The detection method according to claim 10, wherein:
the main body further comprises a power source and a heating element,
wherein the replacement piece further comprises an element to be heated, and the heating element is disposed correspondingly to the element to be heated, and
wherein the power source is configured to supply power to the heating element, and the heating element is used to heat the element to be heated in the replacement piece.

18. The detection method according to claim 10, wherein the main body is an electronic cigarette, and the replacement piece is a cartridge; or the main body is a syringe, and the replacement piece is a disposable needle tube.
